(19) United States
(12) Patent Application Publication
(10) Pub. No.: US 2026/0271423 A1
(43) Pub. Date: Sep. 10, 2026

(54) PHOTODIODE AND MANUFACTURING METHOD THEREOF

(71) Applicant: Taiwan-Asia Semiconductor Corporation, Hsinchu City (TW)

(72) Inventor: Ching-Pu Tai, Hsinchu City (TW)

(21) Appl. No.: 19/264,233

(22) Filed: Jul. 9, 2025

(30) Foreign Application Priority Data
Mar. 10, 2025 (TW) 114108817

(51) Int. Cl. H10F 77/12; H10F 30/222; H10F 71/00

(52) U.S. Cl. CPC H10F 77/12; H10F 30/222; H10F 71/134

(57) ABSTRACT

A photodiode and a manufacturing method thereof are provided. The photodiode comprises a substrate, a first conductive type epitaxial layer, an intrinsic epitaxial layer, a second conductive type in-situ doped epitaxial layer, and a first laser sintered sidewall. The second conductive type in-situ doped epitaxial layer is disposed on the intrinsic epitaxial layer. The first laser sintered sidewall is disposed on an outer periphery of the second conductive type in-situ doped epitaxial layer to define an active region and substantially block external light from entering the second conductive type in-situ doped epitaxial layer through a device sidewall. The device sidewall is collectively defined by the sidewalls of the substrate, the first conductive type epitaxial layer, the intrinsic epitaxial layer, and the second conductive type in-situ doped epitaxial layer, and the first laser sintered sidewall is disposed inside the device sidewall.

### CROSS-REFERENCES TO RELATED APPLICATIONS

This application claims the benefit of priority to Taiwanese Patent Application No. 114108817 filed on Mar. 10, 2025, which is hereby incorporated by reference in its entirety.

### BACKGROUND OF THE INVENTION

### Field of the Invention

This invention relates to a photodiode and a manufacturing method thereof, and in particular to a photodiode with a high signal-to-noise ratio and a manufacturing method thereof.

### Descriptions of the Related Art

A photodiode is an electronic component that converts external optical signals into electrical signals. Its core function is to absorb external light for detecting optical signals and converting them into measurable electrical current. This conversion is critical for various applications, such as optical communication, optical measurement, and image generation.

The mechanism by which a photodiode absorbs external light involves the semiconductor material (e.g., silicon substrate) within the diode absorbing light. When photons enter the photodiode and are absorbed, the energy of the photons can cause electrons in the valence band to transition to the conduction band for generating electron-hole pairs. These photo-generated carriers are separated under the influence of the built-in electric field within the diode for producing an electric current.

However, traditional photodiodes face two issues. First, the P-type doped epitaxial layer on the top surface of traditional photodiodes is typically formed by performing a P-type dopant implantation process and a diffusion process after the epitaxial growth process, ultimately defining the P-type doped epitaxial layer. However, in the P-type doped epitaxial structure formed through diffusion, differences in the concentration gradient of the dopant exist. For example, the concentration gradient profile typically forms a three-dimensional ellipsoid (wider in the middle region and narrower at the upper and lower ends), resulting in varying electric field strengths in the depletion region of the PN junction depending on the diffusion depth. This affects the photo response efficiency and the magnitude of the photo-generated current.

On the other hand, another issue with traditional photodiodes is that, in practical applications, external light can easily enter the device through the exposed device sidewall, causing internal interference. This affects the accuracy of the photosensitive region's operation, leading to computational errors in subsequent applications of related devices. To overcome these issues, there is an urgent need in the industry for an innovative photodiode architecture that not only addresses the uneven P-type doping concentration distribution and improves photo response but also prevents noise and subsequent malfunctions caused by external light penetrating the device sidewall.

### SUMMARY OF THE INVENTION

The primary objective of this invention is to provide an innovative photodiode and a manufacturing method thereof. Compared to traditional photodiodes, the photodiode of this invention uses a P-type in-situ doped epitaxial layer, ensuring that the doping concentration is uniformly distributed within the P-type epitaxial layer to enhance photo response efficiency and increase photo-generated current. Additionally, the photodiode of this invention employs laser sintering to form a laser-sintered sidewall, which defines the active region of the photodiode and blocks external light from entering the active region, thereby avoiding noise interference. This improves the signal-to-noise ratio (SNR) of the photodiode and reduces issues such as malfunctions caused by noise.

To achieve the above objective, this invention provides a photodiode comprising a substrate, a first conductive type epitaxial layer, an intrinsic epitaxial layer, a second conductive type in-situ doped epitaxial layer, and a first laser sintered sidewall. The first conductive type epitaxial layer is disposed on the substrate, the intrinsic epitaxial layer is disposed on the first conductive type epitaxial layer, and the second conductive type in-situ doped epitaxial layer is disposed on the intrinsic epitaxial layer. The first laser sintered sidewall is disposed on an outer periphery of the second conductive type in-situ doped epitaxial layer to define an active region and substantially block external light from entering the second conductive type in-situ doped epitaxial layer through a device sidewall. The device sidewall is collectively defined by sidewalls of the substrate, the first conductive type epitaxial layer, the intrinsic epitaxial layer, and the second conductive type in-situ doped epitaxial layer, and the first laser sintered sidewall is disposed inside the device sidewall.

In one embodiment of the photodiode of this invention, the first laser sintered sidewall is further disposed in the intrinsic epitaxial layer.

In one embodiment of the photodiode of this invention, the first laser sintered sidewall has a length of not less than 1 micrometer (μm) to substantially block external light from entering the second conductive type in-situ doped epitaxial layer through the device sidewall.

In one embodiment of the photodiode of this invention, the device sidewall is a second laser sintered sidewall.

In one embodiment of the photodiode of this invention, the second conductive type in-situ doped epitaxial layer is a P-type in-situ doped indium phosphide (InP) epitaxial layer, with a dopant selected from one of zinc (Zn), magnesium (Mg), or beryllium (Be), and a doping concentration of 10¹⁷ to 10¹⁹ cm⁻³.

In one embodiment of the photodiode of this invention, the photodiode further comprises a metal ring disposed on an upper surface of the second conductive type in-situ doped epitaxial layer at an inner upper edge of the first laser sintered sidewall.

In one embodiment of the photodiode of this invention, a material of the metal ring is selected from the group consisting of chromium (Cr), palladium (Pd), aluminum (Al), titanium (Ti), nickel (Ni), gold (Au), and combinations thereof.

In one embodiment of the photodiode of this invention, the photodiode further comprises an N-type metal disposed on a side of the substrate opposite to the first conductive type epitaxial layer, wherein a material of the N-type metal is selected from the group consisting of germanium (Ge), gold (Au), and combinations thereof.

To achieve the above objective, this invention provides a manufacturing method for a photodiode, comprising the following steps. First, a first conductive type epitaxial layer disposed on a substrate is provided. Next, an intrinsic epitaxial layer disposed on the first conductive type epitaxial layer is provided. Then, a second conductive type in-situ doped epitaxial layer disposed on the intrinsic epitaxial layer is provided. A first laser sintered sidewall disposed on an outer periphery of the second conductive type in-situ doped epitaxial layer is provided to define an active region. Finally, a device sidewall disposed on each sidewall of the substrate, the first conductive type epitaxial layer, the intrinsic epitaxial layer, and the second conductive type in-situ doped epitaxial layer is provided, wherein the first laser sintered sidewall is disposed inside the device sidewall to substantially block external light from entering the second conductive type in-situ doped epitaxial layer through the device sidewall.

In one embodiment of the manufacturing method of the photodiode of this invention, the step of providing a first laser sintered sidewall is to provide a first laser to form the first laser sintered sidewall, disposed on an outer periphery of the second conductive type in-situ doped epitaxial layer and in the intrinsic epitaxial layer.

In one embodiment of the manufacturing method of the photodiode of this invention, the step of providing a first laser sintered sidewall is to provide the first laser sintered sidewall with a length of not less than 1 micrometer (μm) to substantially block external light from entering the second conductive type in-situ doped epitaxial layer through the device sidewall.

In one embodiment of the manufacturing method of the photodiode of this invention, the step of providing a device sidewall is to provide a second laser to form a second laser sintered sidewall, disposed on each sidewall of the substrate, the first conductive type epitaxial layer, the intrinsic epitaxial layer, and the second conductive type in-situ doped epitaxial layer.

In one embodiment of the manufacturing method of the photodiode of this invention, the step of providing a second conductive type in-situ doped epitaxial layer is a step of providing a P-type in-situ doped indium phosphide (InP) epitaxial layer.

In one embodiment of the manufacturing method of the photodiode of this invention, the step of providing a P-type in-situ doped indium phosphide (InP) epitaxial layer is to perform indium phosphide (InP) epitaxial growth using metal-organic chemical vapor deposition (MOCVD) while simultaneously doping with one of zinc (Zn), magnesium (Mg), or beryllium (Be), with a doping concentration of 10¹⁷ to 10¹⁹ cm⁻³.

In one embodiment of the manufacturing method of the photodiode of this invention, the method further comprises a step of providing a metal ring before providing the first laser sintered sidewall, such that the metal ring is disposed on an upper surface of the second conductive type in-situ doped epitaxial layer at an inner upper edge of the first laser sintered sidewall.

In one embodiment of the manufacturing method of the photodiode of this invention, the step of providing a metal ring is to provide a material selected from the group consisting of chromium (Cr), palladium (Pd), aluminum (Al), titanium (Ti), nickel (Ni), gold (Au), and combinations thereof.

In one embodiment of the manufacturing method of the photodiode of this invention, the method further comprises a step of providing an N-type metal disposed on a side of the substrate opposite to the first conductive type epitaxial layer, wherein a material of the N-type metal is selected from the group consisting of germanium (Ge), gold (Au), and combinations thereof.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 to FIG. 6 are cross-sectional schematic diagrams illustrating the manufacturing process of a photodiode in one embodiment of this invention; and

FIG. 7 is a flowchart schematic diagram of the process steps of a photodiode in one embodiment of this invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

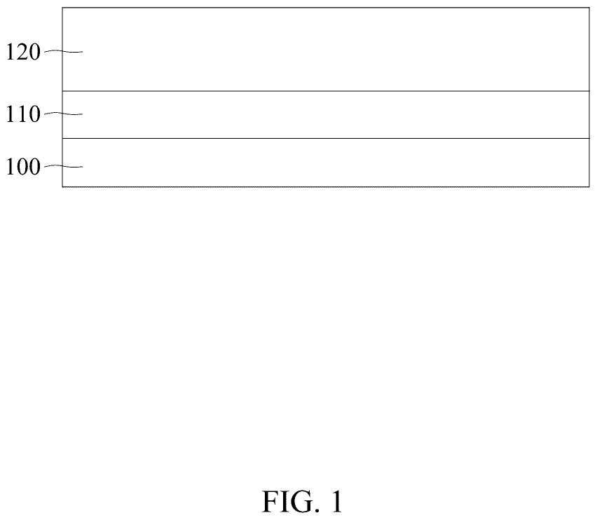

Please refer to FIG. 1 to FIG. 6, which illustrate cross-sectional schematic diagrams of the manufacturing process of a photodiode in one embodiment of this invention. Specifically, this photodiode is a compound semiconductor photodiode. In this embodiment, the manufacturing of the photodiode 10 begins with sequentially forming a first conductive type epitaxial layer 110 and an intrinsic epitaxial layer 120 on a substrate 100, as shown in FIG. 1. Specifically, the substrate 100 may be, but is not limited to, an indium phosphide (InP) substrate. The first conductive type epitaxial layer 110, disposed on the substrate 100, may be an N-type doped epitaxial layer formed using metal-organic chemical vapor deposition (MOCVD), such as, but not limited to, a sulfur (S)-doped indium phosphide (InP) epitaxial layer with a doping concentration of approximately 10¹⁷ to 10¹⁹ cm⁻³, to establish a built-in electric field for driving electron drift. The intrinsic epitaxial layer 120 is an indium gallium arsenide (InGaAs) epitaxial layer disposed on the first conductive type epitaxial layer 110, with a low doping concentration of approximately 10¹⁴ to 10¹⁵ cm⁻³, ensuring a long carrier drift distance, preventing carrier recombination within the intrinsic epitaxial layer, and effectively enabling electron-hole separation and drift, thereby improving photo response efficiency.

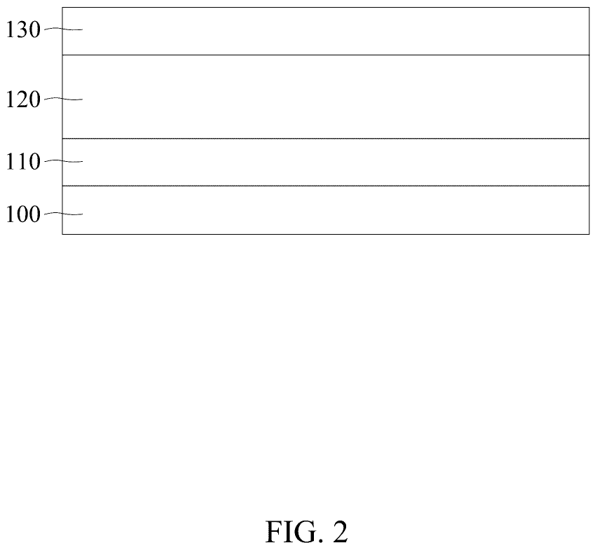

Next, as shown in FIG. 2, a second conductive type epitaxial layer is formed on the intrinsic epitaxial layer 120 using MOCVD. Specifically, unlike the prior art, the second conductive type epitaxial layer in this invention is a second conductive type in-situ doped epitaxial layer 130. That is, the second conductive type in-situ doped epitaxial layer 130 is formed by performing indium phosphide (InP) epitaxy using MOCVD while simultaneously doping with one of zinc (Zn), magnesium (Mg), or beryllium (Be), with a doping concentration of 10¹⁷ to 10¹⁹ cm⁻³, directly forming a P-type in-situ doped indium phosphide (InP) epitaxial layer on the intrinsic epitaxial layer 120. It should be noted that, in traditional photodiodes, the P-type epitaxial layer is typically formed through separate ion implantation and diffusion processes performed after the epitaxial growth. As a result, the doping concentration and diffusion profile are often uneven within the epitaxial structure. In contrast, the “in-situ doping” in the second conductive-type in-situ doped epitaxial layer 130 of this invention refers to simultaneous P-type doping carried out during the layer-by-layer epitaxial growth process. This ensures that the P-type doping concentration is uniformly distributed within the epitaxial structure, thereby achieving the purpose of enhancing photo response efficiency and photo-generated current.

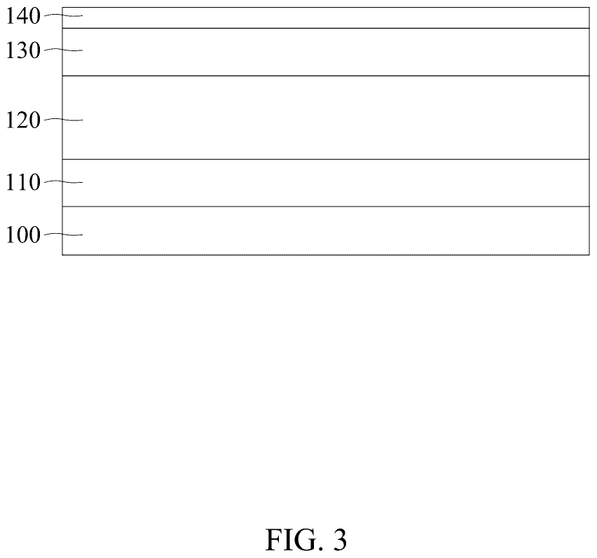

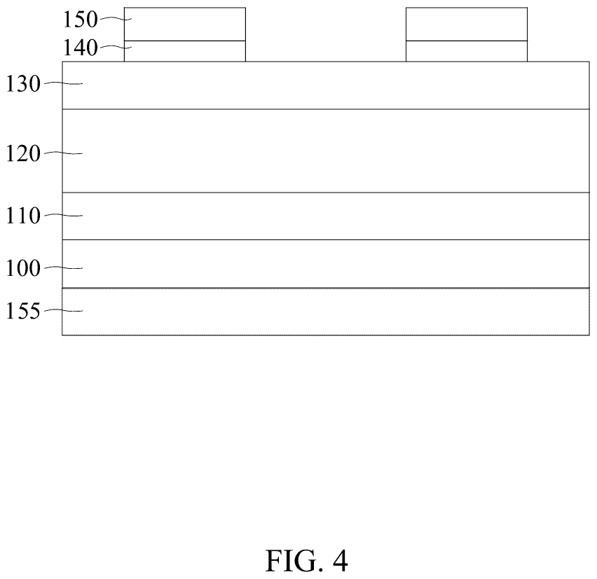

Please refer to FIG. 3, where an ohmic contact epitaxial layer 140 is epitaxially grown on the second conductive type in-situ doped epitaxial layer 130. Specifically, this ohmic contact epitaxial layer 140 may be, but is not limited to, an indium gallium arsenide (InGaAs) epitaxial layer to provide low ohmic contact resistance. Next, a metal layer is formed on the ohmic contact epitaxial layer 140, and a patterning process is used to etch away portions of the metal layer and the ohmic contact epitaxial layer 140, a metal ring 150 and a patterned ohmic contact epitaxial layer 140 are formed on the upper surface of the second conductive type in-situ doped epitaxial layer 130 for serving as the P-type metal electrode of the vertical photodiode of this invention, as shown in FIG. 4. The material of the metal ring 150 is selected from the group consisting of chromium (Cr), palladium (Pd), aluminum (Al), titanium (Ti), nickel (Ni), gold (Au), and combinations thereof. Additionally, an N-type metal 155 is disposed on a side of the substrate 100 opposite to the first conductive type epitaxial layer 110, serving as the N-type metal electrode of the vertical photodiode of this invention, wherein the material of the N-type metal 155 is selected from the group consisting of germanium (Ge), gold (Au), and combinations thereof.

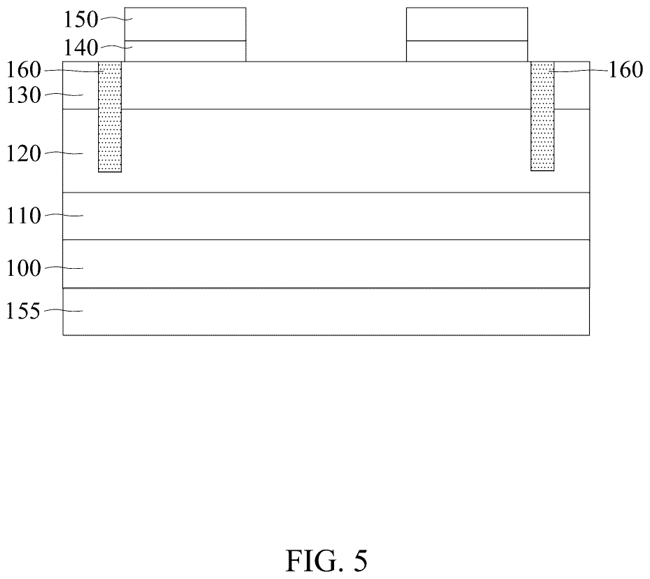

To address the issue of low signal-to-noise ratio in traditional photodiodes caused by external light interference, this invention specifically provides a first laser to form a first laser sintered sidewall 160, disposed on an outer periphery of the second conductive type in-situ doped epitaxial layer 130, to define an active region of the photodiode and substantially block external light from entering the second conductive type in-situ doped epitaxial layer 130, as shown in FIG. 5. In particular, the first laser sintered sidewall 160 is disposed inside the device sidewall, with the metal ring 150 positioned at the inner upper edge of the first laser sintered sidewall 160. Similar with a mesa etching process that defines a mesa, the metal ring 150 and the first laser sintered sidewall 160 collectively define the active region for light absorption, and the first laser sintered sidewall 160 blocks unintended external light from entering the active region through the device sidewall, preventing subsequent malfunctions due to the noises. The aforementioned device sidewall is collectively defined by the sidewalls of the substrate 100, the first conductive type epitaxial layer 110, the intrinsic epitaxial layer 120, and the second conductive type in-situ doped epitaxial layer 130.

Specifically, a green laser or ultraviolet (UV) laser may be used to form a laser-sintered sidewall with a length of not less than 1 micrometer (μm) at the outer periphery of the second conductive type in-situ doped epitaxial layer 130, to substantially block external light from entering the second conductive type in-situ doped epitaxial layer 130. The length of this first laser sintered sidewall 160 may be adjusted based on the specifications of the actual photodiode device. Preferably, the first laser sintered sidewall 160 may further extend into the intrinsic epitaxial layer to ensure that unintended external light does not enter the diode device through the device sidewall for preventing from erroneously trigger noises, while also enhancing the electrostatic protection capability of the photodiode.

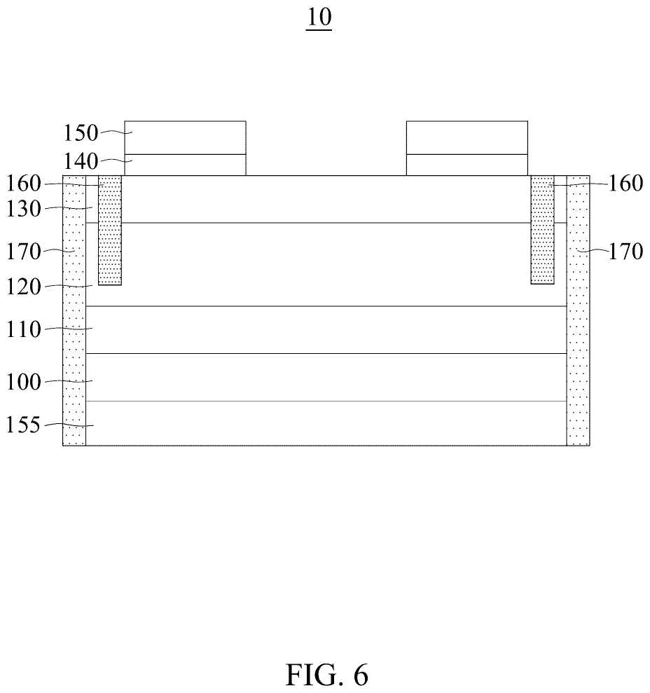

Please refer to FIG. 6, where, finally, the indium phosphide wafer is diced to form individual photodiode devices. Specifically, a second laser is provided. The indium phosphide wafer is thus diced by using laser cutting such that the device sidewall, collectively defined by the sidewalls of the N-type metal 155, the substrate 100, the first conductive type epitaxial layer 110, the intrinsic epitaxial layer 120, and the second conductive type in-situ doped epitaxial layer 130, forms a second laser sintered sidewall 170, resulting in individual photodiode devices 10. It should be noted that, as shown in FIG. 6, it is clearly illustrated that the first laser sintered sidewall 160 is disposed inside the second laser sintered sidewall 170.

On the other hand, although the second laser used for the second laser sintered sidewall 170 employs the same laser source as the first laser, the laser energy and duration used for laser cutting with the second laser differ from those used for laser sintering the epitaxial layer with the first laser. Experimental results indicate that the second laser sintered sidewall 170 formed by laser cutting is insufficient to block unintended external light from entering the device through the device sidewall. Therefore, the photodiode 10 of this invention must include the first laser sintered sidewall 160 to define the active region within the device and simultaneously block unintended external light from entering the device through the device sidewall, which could trigger noise. In particular, since the second conductive type in-situ doped epitaxial layer 130 at the top of the photodiode of this invention has a uniformly distributed doping concentration, it results in significantly improved photo response efficiency. If failure to clearly define the active region for light absorption, it would inevitably reduce the effective signal-to-noise ratio. Thus, this invention incorporates the first laser sintered sidewall 160 in the device structure to clearly define the active region, create a mesa-like effect, and eliminate external noise interference. This achieves the dual benefits of enhancing the device's photo response efficiency and photo-generated current while effectively improving the signal-to-noise ratio, thereby increasing the sensing efficiency and accuracy of the photodiode.

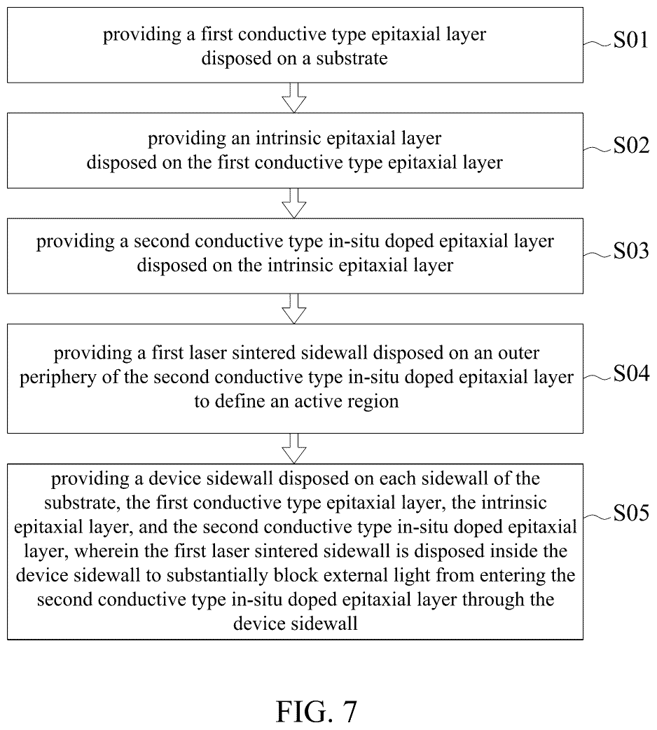

Please refer to FIG. 7, which illustrates a flowchart schematic diagram of the process steps of the photodiode of this invention. First, in step S01, a first conductive type epitaxial layer is provided, disposed on a substrate. Next, in step S02, an intrinsic epitaxial layer is provided, disposed on the first conductive type epitaxial layer. In step S03, a second conductive type in-situ doped epitaxial layer is provided, disposed on the intrinsic epitaxial layer. In step S04, a first laser sintered sidewall is provided, disposed on an outer periphery of the second conductive type in-situ doped epitaxial layer, to define an active region. Finally, in step S05, a device sidewall is provided, disposed on each sidewall of the substrate, the first conductive type epitaxial layer, the intrinsic epitaxial layer, and the second conductive type in-situ doped epitaxial layer, wherein the first laser sintered sidewall is disposed inside the device sidewall to substantially block external light from entering the second conductive type in-situ doped epitaxial layer through the device sidewall. The descriptions of the related components can be referred to the above content and will not be repeated here.

The above embodiments are provided to illustrate the implementations of the present invention and to explain its technical features, and are not intended to limit the scope of the present invention. Any modifications or equivalent arrangements that can be easily accomplished by those skilled in the art fall within the scope of the present invention, and the scope of the present invention should be defined by the claims.

What is claimed is:

1. A photodiode, comprising:
a substrate;
a first conductive type epitaxial layer disposed on the substrate;
an intrinsic epitaxial layer disposed on the first conductive type epitaxial layer;
a second conductive type in-situ doped epitaxial layer disposed on the intrinsic epitaxial layer; and
a first laser sintered sidewall disposed on an outer periphery of the second conductive type in-situ doped epitaxial layer to define an active region and substantially block external light from entering the second conductive type in-situ doped epitaxial layer through a device sidewall, wherein the device sidewall is collectively defined by sidewalls of the substrate, the first conductive type epitaxial layer, the intrinsic epitaxial layer, and the second conductive type in-situ doped epitaxial layer, and the first laser sintered sidewall is disposed inside the device sidewall.

2. The photodiode of claim 1, wherein the first laser sintered sidewall is further disposed in the intrinsic epitaxial layer.

3. The photodiode of claim 1, wherein the first laser sintered sidewall has a length of not less than 1 micrometer (μm) to substantially block the external light from entering the second conductive type in-situ doped epitaxial layer through the device sidewall.

4. The photodiode of claim 1, wherein the device sidewall is a second laser sintered sidewall.

5. The photodiode of claim 1, wherein the second conductive type in-situ doped epitaxial layer is a P-type in-situ doped indium phosphide (InP) epitaxial layer, with a dopant selected from one of zinc (Zn), magnesium (Mg), or beryllium (Be), and a doping concentration of 10¹⁷ to 10¹⁹ cm⁻³.

6. The photodiode of claim 1, further comprising a metal ring disposed on an upper surface of the second conductive type in-situ doped epitaxial layer at an inner upper edge of the first laser sintered sidewall.

7. The photodiode of claim 6, wherein a material of the metal ring is selected from the group consisting of chromium (Cr), palladium (Pd), aluminum (Al), titanium (Ti), nickel (Ni), gold (Au), and combinations thereof.

8. The photodiode of claim 1, further comprising an N-type metal disposed on a side of the substrate opposite to the first conductive type epitaxial layer, wherein a material of the N-type metal is selected from the group consisting of germanium (Ge), gold (Au), and combinations thereof.

9. A manufacturing method for a photodiode, comprising:
providing a first conductive type epitaxial layer disposed on a substrate;
providing an intrinsic epitaxial layer disposed on the first conductive type epitaxial layer;
providing a second conductive type in-situ doped epitaxial layer disposed on the intrinsic epitaxial layer;
providing a first laser sintered sidewall disposed on an outer periphery of the second conductive type in-situ doped epitaxial layer to define an active region; and
providing a device sidewall disposed on each sidewall of the substrate, the first conductive type epitaxial layer, the intrinsic epitaxial layer, and the second conductive type in-situ doped epitaxial layer, wherein the first laser sintered sidewall is disposed inside the device sidewall to substantially block external light from entering the second conductive type in-situ doped epitaxial layer through the device sidewall.

10. The manufacturing method for a photodiode of claim 9, wherein the step of providing a first laser sintered sidewall is to provide a first laser to form the first laser sintered sidewall, disposed on an outer periphery of the second conductive type in-situ doped epitaxial layer and in the intrinsic epitaxial layer.

11. The manufacturing method for a photodiode of claim 9, wherein the step of providing a first laser sintered sidewall is to provide the first laser sintered sidewall with a length of not less than 1 micrometer (μm) to substantially block the external light from entering the second conductive type in-situ doped epitaxial layer through the device sidewall.

12. The manufacturing method for a photodiode of claim 9, wherein the step of providing a device sidewall is to provide a second laser to form a second laser sintered sidewall, disposed on each sidewall of the substrate, the first conductive type epitaxial layer, the intrinsic epitaxial layer, and the second conductive type in-situ doped epitaxial layer.

13. The manufacturing method for a photodiode of claim 9, wherein the step of providing a second conductive type in-situ doped epitaxial layer is to provide a P-type in-situ doped indium phosphide (InP) epitaxial layer.

14. The manufacturing method for a photodiode of claim 13, wherein the step of providing a P-type in-situ doped indium phosphide (InP) epitaxial layer is to perform indium phosphide (InP) epitaxial growth using metal-organic chemical vapor deposition (MOCVD) while simultaneously doping with one of zinc (Zn), magnesium (Mg), or beryllium (Be), with a doping concentration of 10¹⁷ to 10¹⁹ cm⁻³.

15. The manufacturing method for a photodiode of claim 9, further comprising a step of providing a metal ring before providing the first laser sintered sidewall, such that the metal ring is disposed on an upper surface of the second conductive type in-situ doped epitaxial layer at an inner upper edge of the first laser sintered sidewall.

16. The manufacturing method for a photodiode of claim 15, wherein the step of providing a metal ring is to provide a material selected from the group consisting of chromium (Cr), palladium (Pd), aluminum (Al), titanium (Ti), nickel (Ni), gold (Au), and combinations thereof.

17. The manufacturing method for a photodiode of claim 9, further comprising a step of providing an N-type metal disposed on a side of the substrate opposite to the first conductive type epitaxial layer, wherein a material of the N-type metal is selected from the group consisting of germanium (Ge), gold (Au), and combinations thereof.
